(19) United States
(12) Patent Application Publication
(10) Pub. No.: US 2012/0024694 A1
(43) Pub. Date: Feb. 2, 2012

(54) Triangular Scanning Magnet in Sputtering Tool Moving Over Larger Triangular Target

(75) Inventors: Ravi Mullapudi, San Jose, CA (US); Srikanth Dasaradhi, San Jose, CA (US); Edward Sterpka, Brentwood, CA (US); Biju Ninan, Cupertino, CA (US)

(73) Assignee: TANGO SYSTEMS, INC., San Jose, CA (US)

(21) Appl. No.: 12/846,752

(22) Filed: Jul. 29, 2010

(51) Int. Cl. C23C 14/35; C23C 14/54

(52) U.S. Cl. 204/192.12; 204/298.16

(57) ABSTRACT

A sputtering chamber contains a plurality of substantially triangular targets supported by a top wall. The targets have narrow ends pointing toward a center of the top wall. Above each target is a relatively small substantially triangular magnet. Each magnet is connected to a single central actuator that scans all magnets back and forth through an arc across its associated target. Each magnet is also movably connected to an arm connected to the central scanning actuator. A linear actuator moves each magnet up and down the arm simultaneously with the angular scanning movement. The combination of the simultaneous angular movement and linear movement (perpendicular to the arc) of the magnet causes each magnet to move only over a substantially triangular area corresponding to an area of an associated target. In one embodiment, the linear speed of the magnets is varied to achieve uniform erosion of the target.

### FIELD OF THE INVENTION

This invention relates to sputtering systems and, in particular, to a magnetron for use in a sputtering system.

### BACKGROUND

Sputtering systems are widely used in the semiconductor manufacturing industry for depositing materials on semiconductor wafers. Sputtering is sometimes referred to as physical vapor deposition, or PVD. In a sputtering operation, thin films comprising materials such as Al, Au, Cu, Ta are deposited in a vacuum on silicon wafers or other substrates.

The present assignee has obtained a U.S. Pat. No. 7,479,210 on a sputtering tool, which is shown in the prior art FIGS. 1 and 2. Related applications using the same specification are pending. U.S. Pat. No. 7,479,210 is incorporated herein by reference.

Prior art FIG. 1 is a cutaway view of a sputtering system 12 for workpieces such as semiconductor wafers, LCD panels, and other workpieces requiring the deposition of thin films. Examples of thin films include Al, Cu, Ta, Au, Ti, Ag, Sn, NiV, Cr, TaNx, Hf, Zr, W, TiW, TiNx, AlNx, AlOx, HfOx, ZrOx, TiOx, magnetic films, and various alloys of these materials. The system 12 is completely described in the present assignee's U.S. Pat. No. 7,479,210 and only a brief summary is provided.

Since the present invention is a new magnetron assembly, shown in FIGS. 3 and 4, that replaces the magnetron in prior art FIG. 1, the resulting system is the system of FIG. 1 but employing the magnetron of FIGS. 3 and 4. Therefore, the below description of the system 12 is provided to describe a preferred environment of the new magnetron.

The top cover of the sputtering system 12 has been removed. A robotic arm (not shown) in a wafer transport module inserts and removes wafers 41 via the access port 14. Typical wafer sizes are 6, 8, and 12 inches, and the system is customized for the particular workpieces for processing.

In one embodiment, the system 12 simultaneously processes three or more wafers 41 (preferably five or six) using three or more sputtering targets 43.

A pallet 36 rotates to align a wafer 41 below an appropriate target 43. Each target 43 may be a different material for forming successive thin films of different materials on a wafer 41. The wafers 41 are supported on wafer support areas 32. A wafer support area 32 is an indented area in pallet 36 sized to accommodate the particular wafers being processed.

Four pins (not shown) below pallet 36 are raised, using pin bellows 39, to extend through four holes in the wafer support area 32 to temporarily lift the wafer 41 during insertion of the wafer 41 into the chamber and removal of the wafer 41 from the chamber.

The pallet 36 is mounted on a rotatable table 40. Pallet 36 and table 40 may be formed of aluminum. Pallet 36 may be continuously rotated at any speed or may be temporarily stopped to control the deposition of a sputtered material from a target 43 overlying a wafer.

A chamber shield 35 prevents contaminants from accumulating on the vacuum chamber wall.

FIG. 2 is a cross-sectional view of pallet 36 and table 40. Pallet 36 is a single piece that is fixed to table 40 by a countersunk screw 42 at the indentation in each wafer support area 32 so that the wafers block the sputtered materials being deposited on screws 42. Pallet 36 may be removed for cleaning by unscrewing screws 42.

The entire back surface of each wafer is thus in electrical and thermal contact with pallet 36, which is in turn in electrical and thermal contact with table 40.

The temperature of the wafers is controlled by flowing a coolant 44 (FIG. 2) through a copper tube 46 in direct contact with table 40. The copper tube 46 runs in a groove 48 around the table 40. The copper tube 46 extends up through a rotating shaft 49 attached to table 40.

An external cooling source 50 cools the coolant (e.g., water) and recycles the coolant back to table 40. Flexible tubing 51 from the cooling source 50 attaches to a rotatable coupler 52 for providing a sealed coupling between the rotating copper tubes 46 (input and output) and the stationary tubing 51 to/from the cooling source 50.

An RF and DC bias source 54 is electrically coupled to the copper tube 46 by the rotatable coupling 52 to energize table 40 and thus energize pallet 36 and the wafers for the sputtering process. In another embodiment, table 40 is grounded, floated, or biased with only a DC voltage source.

When the chamber is evacuated and back filled with a certain amount of Ar gas at a certain pressure (for example, 20 milli-torr) and the gas is energized with a DC source, an RF source, or a combination of the two sources, an electromagnetic field is coupled inside the chamber to excite a sustained high density plasma near the target surface. The plasma confined near the target surface contains positive ions (such as Ar+) and free electrons. The ions in the plasma strike the target surface and sputter material off the target. The wafers receive the sputtered material to form a deposited layer on the surface of the wafers. In one instance, up to twenty kilowatts of DC power can be provided on each target. In such a case, each target can deposit approximately 1 micron of metal per minute on an underlying work piece.

The chamber wall is typically electrically grounded in processing operations.

A bias voltage on the wafers can drive a flux of an electrically charged species (Ar+ and/or atomic vapor sputtered off the target) to the wafers. The flux can modify the properties (for example, density) of the sputtered material to the wafers.

Generating a plasma for sputtering and the various biasing schemes are well known, and any of the known techniques may be implemented with the described sputtering system.

In a preferred embodiment, the chamber gas is provided by a distribution channel at the bottom of the chamber, rather than from the top, which reduces particle contamination during the sputtering process and allows optimization of the magnetron assembly.

FIG. 1 illustrates a motor 58 for rotating shaft 49. Shaft 49 is directly coupled to the motor 58 so that pallet 36 is directly driven by motor 58. The motor 58 surrounds shaft 49 and has a central rotating sleeve fixed to shaft 49. Motor 58 may be a servo or stepper motor. In one embodiment, the motor is a servo motor that uses an absolute encoder attached to shaft 49 to determine the angular position of shaft 49. A typical RPM of pallet 36 during the deposition process is 5-30 RPM.

A seal 57 provides a seal around shaft 49 in order to maintain a low pressure in the chamber.

A cross-contamination shield 96 helps confine sputtered material to an area under the target.

The sputtering system 12 uses a magnetron assembly, outside the vacuum, to further control the bombardment of the target by the plasma. A magnet 60 is located behind each target 43 so that the plasma is confined to the target area. The resulting magnetic field forms a closed-loop annular path acting as an electron trap that reshapes the trajectories of the secondary electrons ejected from target into a cycloidal path, greatly increasing the probability of ionization of the sputtering gas within the confinement zone. Inert gases, specifically argon, are usually employed as the sputtering gas because they tend not to react with the target material or combine with any process gases and because they produce higher sputtering and deposition rates due to their high molecular weight. Positively charged argon ions from the plasma are accelerated toward the negatively biased target and impact the target, resulting in material being sputtered from the target surface.

FIG. 1 illustrates one of the three prior art magnets 60 overlying a target backing plate 59, where the target backing plate 59 is supported by and electrically insulated from a grounded top plate 62 in the sputtering system 12. An insulating bracket 67 secures each magnet 60 to a scanning actuator 66 (e.g., a reciprocating motor) so that there is a minimum gap between the oscillating magnet 60 and the target backing plate 59. Magnet 60 has a substantially triangular or delta shape with rounded corners and has about the same length as the substantially triangular target 43 but narrower. Two other identical magnets (not shown) are located above two other targets centered at 120 degree intervals. The actuator 66 is controlled by a controller to oscillate the three magnets 60 back and forth in unison over their associated targets at an oscillating period of between 0.5-10 seconds. The magnets 60 are oscillated so that the magnetic fields are not always at the same position relative to the target. By distributing the magnetic fields evenly over the target, target erosion is more uniform.

The size of magnets 60 depends on the size of the wafers, which determines the size of the targets. In one embodiment, a magnet 60 is about 10.7 inches (27 cm) long and about 3 inches (7.6 cm) wide at its widest part. An eight inch wafer may use a target that is from 10-13 inches long in the radial direction. A twelve inch wafer may use a target that is from 13-18 inches long in the radial direction.

Since the plasma makes the targets hot, a coolant channel is provided in each target support plate 59 through which a coolant flows. The highest heat is generated under the magnet 60. Adequate and uniform cooling becomes a problem for high density plasmas.

The structure of FIG. 1 has been improved by the assignee by providing a vertical wall of confining magnets surrounding the target 43 and extending downward toward the pallet. The wall of confining magnets confines the sputtered ions to an area over the wafer 41 and directs the sputtered ions in a more normal path relative to the wafer surface. The improved sputtering system is described in U.S. application Ser. No. 12/239,644, filed Sep. 26, 2008, entitled Confining Magnets in Sputtering Chamber, incorporated herein by reference.

Although the sputtering system 12 is very good, there is a practical limit on the ionization power that is supplied to maintain a high sputtering rate. The scanning magnet 60 covers approximately one-half the target at any instant, and the ionization power must be sufficient to create a high density plasma in the area of each target being influenced by the relatively large area magnetic field for a desired high sputtering rate. Such high power requires a large amount of cooling of the target backing plate 59 via the coolant channel in the plate 59. Uneven cooling of the target results in nonuniform sputtering and erosion.

Additionally, the large magnet causes some nonuniform erosion/sputtering of the target due to some target areas being subjected to different average magnetic fluxes over time.

What is needed is an improved sputtering system 12, using mostly its existing components, that achieves a higher sputtering rate with the same ionization power and cooling of the target, and which provides more uniform erosion of the target.

### SUMMARY

In a preferred embodiment, each of the large scanning magnets in FIG. 1 is replaced with a much smaller substantially triangular magnet that is controlled to move linearly along the length of the substantially triangular target as well as simultaneously scanned in an arc by a scanning actuator. After a complete cycle, the small magnet has moved over a substantially triangular area substantially corresponding to the shape of the target. The scanning magnet will typically be one-quarter to one-half the size of the magnet in FIG. 1.

In one embodiment, the same central scanning actuator of FIG. 1 has connected to it three arms, each connected to a relatively small magnet. Each arm includes a motor that rotates a screw gear connected to a back surface of the magnet to move the magnet linearly up and down the arm while the arm is simultaneously scanning back and forth in a small arc across the target. The motor reverses direction when the magnet reaches the end of the target. After one or more cycles of the linear and scanning movements of the magnet, the magnet covers a substantially triangular area corresponding to the area of the target.

The smaller magnet exhibits about the same magnetic flux density (gauss) as the larger magnet of FIG. 1. In one embodiment, the smaller magnet is moved over the entire surface of the target within a cycle of about 1-5 seconds to achieve the same sputtering rate as the larger magnet scanning over the surface of the target during the same period. The inventors have found that higher ionization (power density) was achieved at the target compared to the ionization using the larger magnet of FIG. 1, with the same input power, due to a surprising phenomenon. The particular movement of the smaller magnet over the target also resulted in more uniform erosion of the target.

The relative cycle periods of the linear motor and scanning actuator are set so that, over a suitable time period, the magnet scans over substantially the entire surface of the target. Such suitable cycles depend on the particular shapes of the target and magnet. In one embodiment, the linear motor varies its speed depending on the position of the magnet along the screw gear, such as to slow the linear movement of the magnet near the wide end of the target, while the magnet scans through arcs at a constant rate, to achieve uniform coverage of the target by the magnet. In other words, the linear movement of the magnet is varied so that the magnet overlies all portions of the target about equal times during a complete cycle. In one embodiment, the magnet moving along the linear path actually stops (dwells) at one or more positions along the path, such as at the widest portion of the target, while the magnet continuously scans through arcs back and forth across the target. Such dwells times at various positions are for the purpose of achieving a desired erosion over the entire surface of the target.

In one embodiment, the target is 15-17 inches long, requiring the arm to be a similar length.

The new magnetron may be used in conjunction with the system of FIG. 1 or any other suitable system using substantially triangular targets. The triangular targets enable multiple targets to be used in a circular chamber in conjunction with a rotating pallet that positions wafers beneath suitable ones of the targets for a compact and versatile sputtering system.

### BRIEF DESCRIPTION OF THE DRAWINGS

FIG. 1 is a cutaway view of the present assignee's prior art sputtering tool.

FIG. 2 is a cross-sectional view of the rotating shaft, table, and pallet in the prior art sputtering tool of FIG. 1.

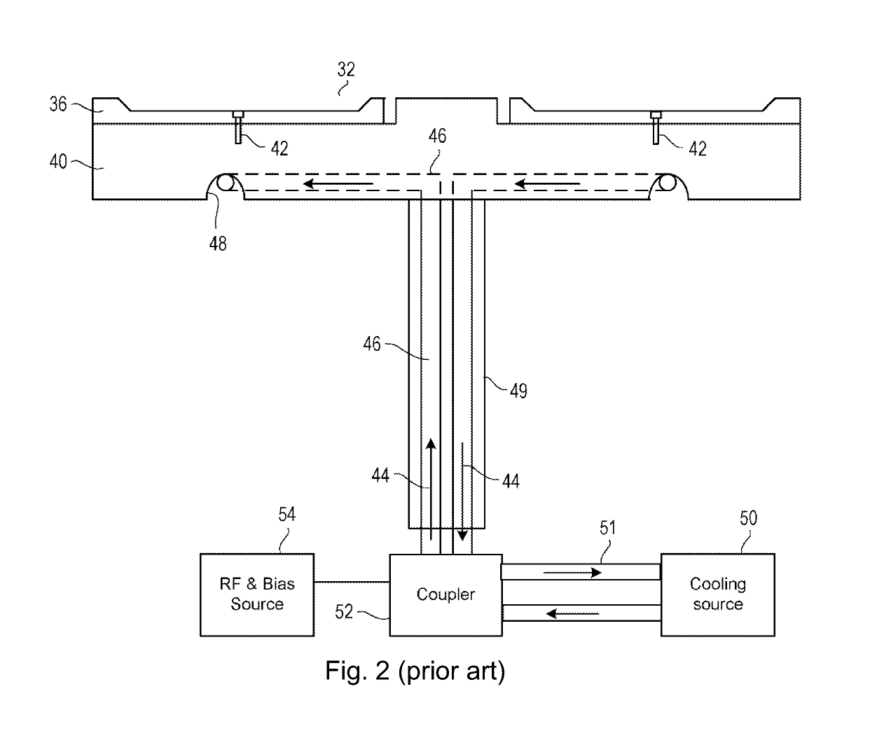

FIG. 3 is a bottom up view of a portion of an inventive magnetron to replace the prior art magnetron of FIG. 1.

FIG. 4 is a top down view of the complete magnetron simultaneously scanning three substantially triangular magnets over three larger substantially triangular targets.

FIG. 5 is a bottom up view of a single magnet illustrating the layout of small magnets mounted on a plate in a substantially triangular pattern.

Elements with the same numbers in the various figures are the same.

### DETAILED DESCRIPTION

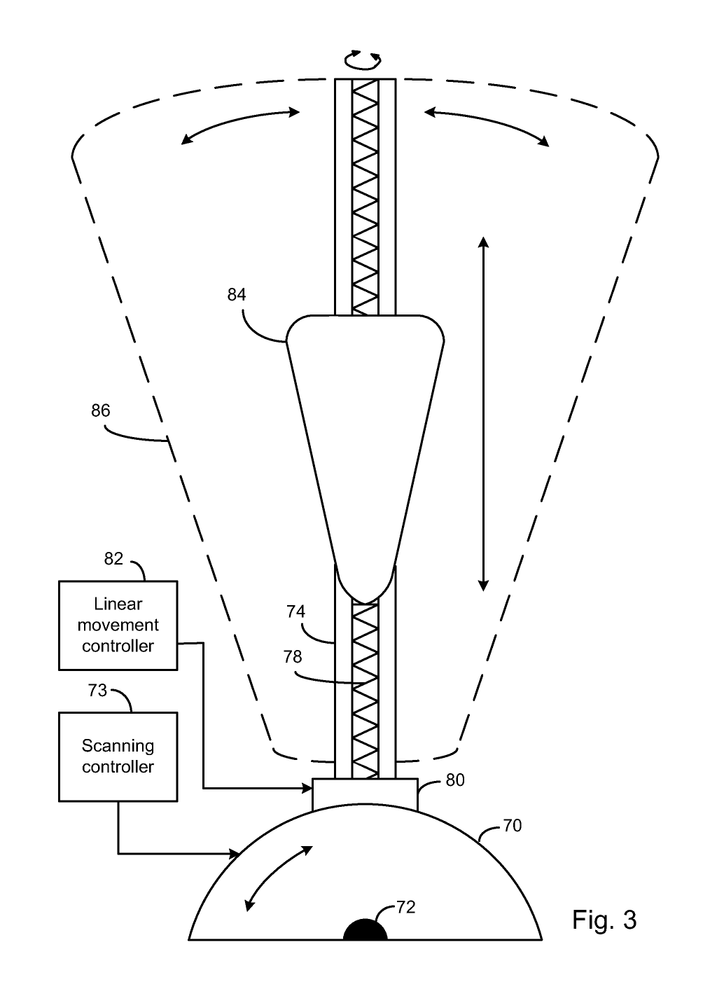

FIG. 3 is a bottom up view of the magnetron, looking up through the top wall of the vacuum chamber.

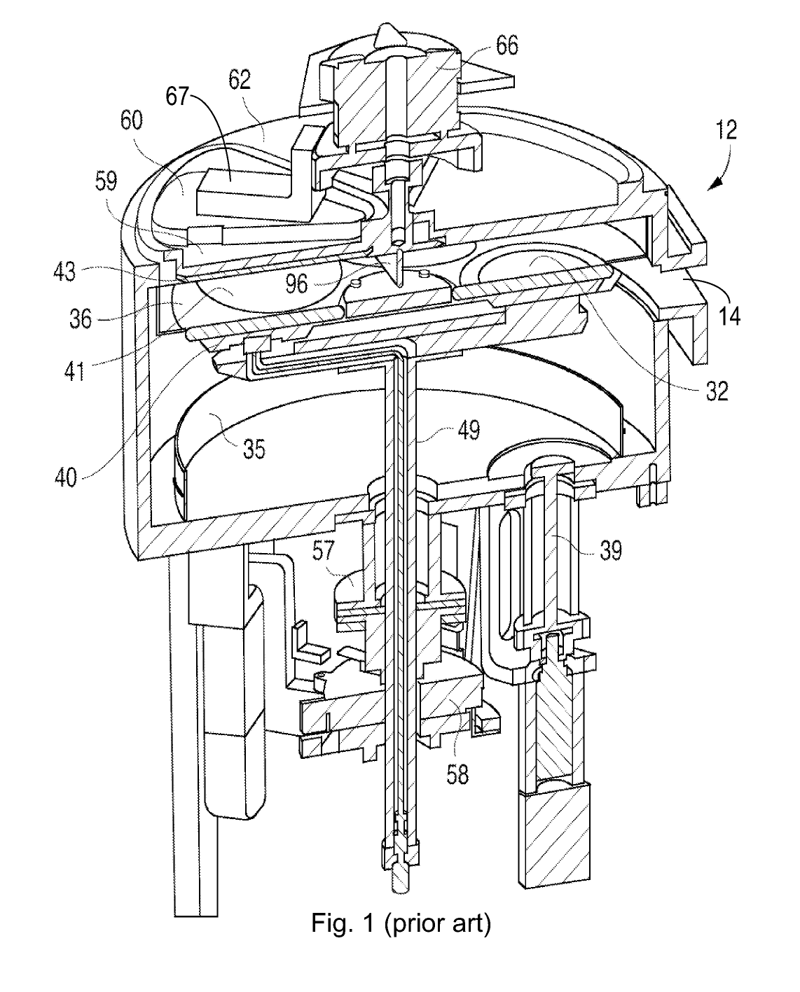

A scanning actuator 70, located at the center of the top wall of the chamber, rotates through an arc about axis 72 and then reverses. The actuator 70 may the same as actuator 66 in FIG. 1.

A scanning controller 73 controls the actuator 70 to rotate through a predetermined angle (less than 120 degrees) and then reverse direction.

Attached to the actuator 70 and extending radially is an arm 74. The arm 74 comprises a support beam with a slot. Within the slot is a screw gear 78. A motor 80 at the base of the arm 74 is connected to the screw gear 78 for turning the screw gear 78 in one direction through a predetermined angular rotation and then turning the screw gear 78 in the opposite direction through a predetermined angular rotation. The motor 80 may be a servo motor or a stepper motor.

A linear movement controller 82 controls the motor 80 speed and direction. Since the speed can be variable during a single cycle, the controller 82 is programmable.

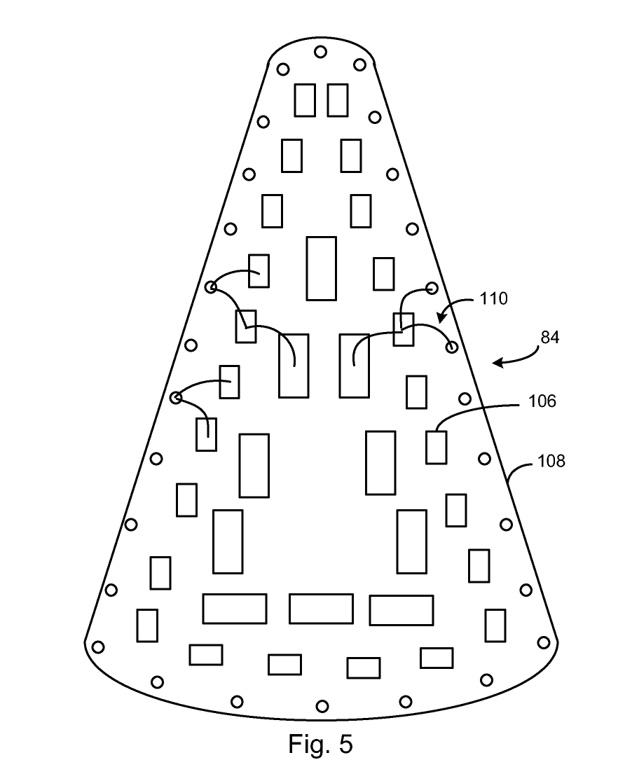

A permanent magnet 84 has a substantially triangular shape, being formed of three straight edges and rounded corners. The magnet 84 comprises a ferrous backing plate populated with a pattern of relatively small magnets affixed to the plate. The magnet 84 will be described in more detail later with respect to FIG. 5. Many different embodiments of magnets may be suitable.

The view of FIG. 3 is of the front of the magnet 84 that faces the target 86. The target 86 is shown in dashed outline since the view of FIG. 3 is through the target 86, through the top wall of the chamber, and through the target backing plate.

Affixed to the back of the magnet's backing plate is a standard screw gear threaded sleeve that receives the screw gear 78 so that rotation of the screw gear 78 causes the magnet 84 to move linearly with respect to the arm 74 while remaining in a single plane.

As the scanning actuator 70 scans at a constant rate, the motor 80 moves the magnet 84 at either a constant speed or a varying speed up and down the length of the target 86 so that ultimately the magnet 84 covers substantially the entire area of the triangular target 86 after one or more cycles of the repetitive angular and linear movement of the magnet. In one embodiment, the actuator 70 completes a back and forth scan in between 1-3 seconds, and the motor 80 completes and up and down movement of the magnet between 1-5 seconds. The cycle times may be greater or less than these periods, depending on the sizes of the target and magnet.

Due to the triangular shape of the target 86, to achieve uniform coverage of the target 86 by the magnet 84, the linear motor 80 varies its speed depending on the position of the magnet 84 along the screw gear 78. For example, the linear movement of the magnet 84 is slowed near the wide end of the target, and may even be dwelled, while the magnet scans through arcs at a constant rate. In other words, the linear movement of the magnet may be varied so that the magnet overlies all portions of the target about equal times during a complete cycle. Additionally, due to edge effects, the plasma may not be uniformly created across the surface of the target 86, and the linear speed of the magnet 84 may be controlled to vary to cause substantially uniform erosion of the target even though the magnet 84 does not overlie all portions of the target 86 for equal times during a complete cycle. For example, the speed of the magnet 84 may need to be slowed or dwelled at the narrow end of the target 86. The variation in speed may be programmed into the controller 82 based upon empirical data after long periods of testing and examining the erosion of the target 86.

In one embodiment, the variation in linear speed may not repeat for each linear scan of the magnet 84 in order to achieve full coverage of the target.

In one embodiment, the magnet moving along the linear path actually stops (dwells) at one or more positions along the screw gear, such as at the widest portion of the target 86, while the magnet continuously scans through arcs back and forth across the target. Such dwells times at various positions are for the purpose of achieving a desired erosion (e.g., uniform erosion) over the entire surface of the target. Without such dwelling, certain areas of the target may be overlapped by the magnet more than others due to the multi-direction scanning of the magnet, or some areas may be not covered due to the interaction of the multi-direction scanning. In one embodiment, the magnet dwells at a position along the screw gear for up to five seconds by stopping the linear motor 80. Such control by the linear motor 80 is programmed into the motor's controller and may be based on computer simulation and actual testing results. When a dwell time is used, a period for the motor 80 to move the magnet up and down the arm 74 may exceed 20 seconds.

In one embodiment, the magnet 84 has a shape generally corresponding to the shape of the target but smaller in all dimensions. The magnet will typically be between one-quarter to one-half the size of the target. Since the magnet 84 is smaller than a magnet having the same length as the target, it must be scanned along the length of the target to fully cover the target over time. The smaller magnet will create a higher power density, compared to a full-length bigger magnet, for the same input power into the system because all the power is concentrated in a smaller footprint. This increases the ion concentration at the target, which increases the deposition rate.

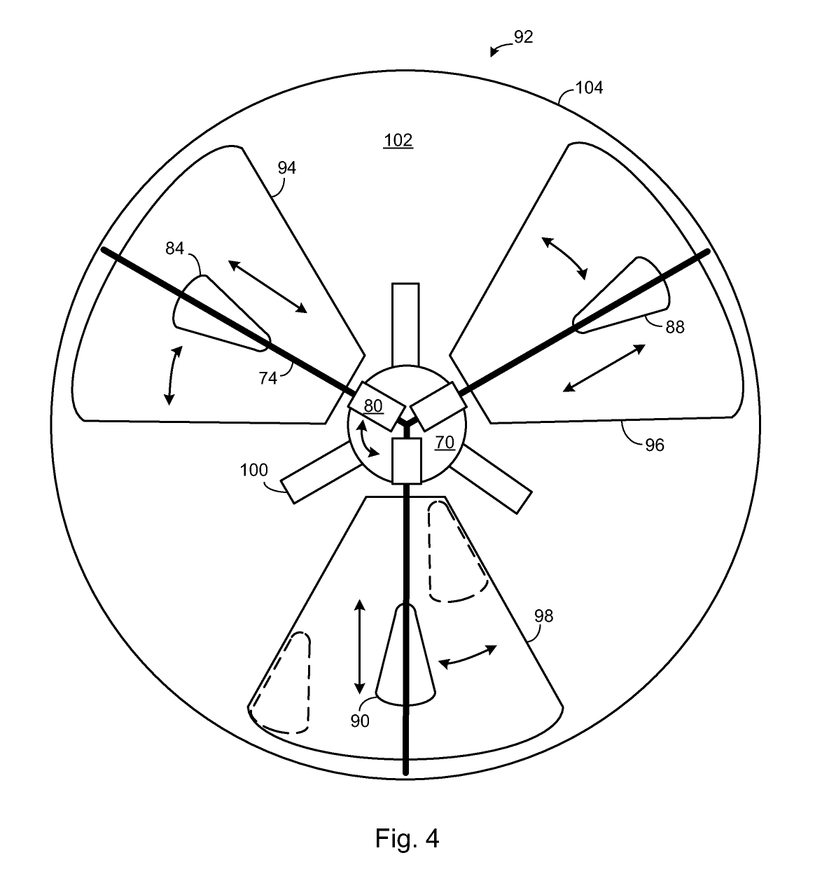

FIG. 4 is a top down view illustrating three magnets 84, 88, and 90 in a sputtering system 92. Target backing plates 94, 96, and 98 are shown, where the targets inside the vacuum chamber are affixed to the undersides of the target backing plates 94, 96, and 98 and have the same general shape and size as the plates 94, 96, and 98. Each magnet is connected to an arm identical to the arm 74 in FIG. 3. All the motors for the screw gears 78 (FIG. 3) may be controlled identically by the single linear movement controller 82. The magnets may all be identical and the sizes of the targets may all be identical but may be composed of different materials. The amount of sputtering is dependent on the time that the wafer is below the target, the plasma density, the biasing voltages, and other factors.

In FIG. 4, ghost images of the magnet 90 are shown in dashed outline to show two positions of the magnet 90 during a scanning cycle at two instances in time, and the magnet 90 will ultimately overlap all areas of the target after a certain period, then repeat the cycle so that the moving magnetic field generated by the magnet over time will have covered a substantially triangular shape and provide a substantially uniform erosion of the target, resulting in uniform sputtering onto the underlying wafer 41 (FIG. 1).

FIG. 4 also shows a support structure 100 that affixes the scanning actuator 70 on the top wall 102 of the chamber. An outer wall 104 of the chamber is shown, which defines the outer perimeter of the substantially circular top wall 102 of the vacuum chamber that supports the electrically insulated target backing plates 94, 96, and 98. The top wall insulation is described in detail in U.S. Pat. No. 7,479,210 discussed above. By making the targets and target backing plates substantially triangular, at least three targets can be arranged around the circular chamber, resulting in a very compact sputtering system.

FIG. 5 illustrates one possible arrangement of magnets 106 on a ferrous backing plate 108. There are three rings (nested patterns) of individual magnets 106, where adjacent rings have opposite poles so that a magnetic field spans across one ring to the next. Some magnetic field lines 110 are shown. Since there are three rings of magnets, there are two racetracks of field lines. These magnetic fields pass through the target backing plate 59 (FIG. 1) and intersect the target 43 (or 94, 96, 98 in FIG. 4) attached to the underside of the target backing plate 59. The plasma density at the target (and thus the erosion rate) is greatest at the highest magnetic field intensity. The sizes, shapes, and distribution of the individual magnets 106 are selected to create a uniform erosion of the target as the magnet is scanned over the target.

The individual magnets 106 along the edge of magnet 84 are smaller that the inner magnets so that the magnetic field extends close to the edge of the magnet. The span of a magnetic field can be approximated by the distance between the centers of the two opposite poles. Hence, the diameters of the outer magnets 106 are made small (e.g., 0.5-1 cm). The inner rings of magnets 106 may be larger. In the example, the magnets 106 may be rectangular or circular.

The magnetron assembly of FIG. 4 simply replaces the magnetron assembly of FIG. 1 with no other changes to the system.

The described sputtering system allows for all three targets to concurrently sputter the same or different materials on the wafers during a batch process. This increases throughput and allows the sputtering of alloys or layers on the wafers without breaking a vacuum. To select an alloy composition, one target may be one material, and the other two targets may be a second or third material. For depositing stacked layers of distinct materials, then only one material may be deposited at a time (e.g., one target energized at a time or multiple targets of the same material energized at a time). For depositing mixed layers (e.g. alloys of distinct materials), then all targets may be energized at the same time, assuming the targets are of different materials.

More targets and wafers than shown in the examples may be employed in the system. For example, there may be eight targets. The number of such targets is limited only by the ability to build increasingly narrow magnets, which deliver a suitable magnetic flux on the target surface.

Conventional aspects of the system that have not been described in detail would be well known to those skilled in the art. U.S. Pat. No. 6,630,201 and U.S. Patent Application Publication 2002/0160125 A1 are incorporated herein by reference for certain conventional aspects primarily related to creating a plasma and supplying gas to a process chamber.

Although the system has been described with respect to forming a metal film on semiconductor wafers, the system may deposit any material, including dielectrics, and may process any workpiece such as LCD panels and other flat panel displays. In one embodiment, the system is used to deposit materials on multiple thin film transistor arrays for LCD panels.

Having described the invention in detail, those skilled in the art will appreciate that, given the present disclosure, modifications may be made to the invention without departing from the spirit and inventive concepts described herein. Therefore, it is not intended that the scope of the invention be limited to the specific embodiments illustrated and described.

What is claimed is:

1. A sputtering device comprising:
a chamber having at least one workpiece support area for receiving a workpiece, the chamber having walls, the chamber being sealable to create a low pressure environment in the chamber while sputtering materials on the workpiece, the chamber having a substantially circular top wall;
a substantially triangular target positioned within the chamber in a first plane, a front side of the target being directed into the chamber for sputtering material from the target onto the workpiece, the target having a narrow end facing a center of the chamber, the target having a first side opposite to the narrow end and having a second side and a third side extending between the narrow end and the first side;
a substantially triangular magnet opposing a back side of the target, the magnet being in a second plane substantially parallel to the first plane, the magnet being substantially smaller than the target;
a first actuator connected to the magnet for scanning the magnet back and forth over the target in an arc, only within the second plane, between the second side and third side of the target during a sputtering operation, the first actuator being located over a center area of the top wall; and
a second actuator connected to the magnet and the first actuator, the second actuator comprising an arm connected to the first actuator, the magnet being movably connected to the arm, the second actuator for moving the magnet in a straight path along the arm in two opposite directions, substantially perpendicular to the arc, between the narrow end of the target and the first side of the target during a sputtering operation,
wherein a combination of the first actuator scanning the magnet in the arc and the second actuator moving the magnet, the magnet moves only over a substantially triangular area corresponding to an area of the target.

2. The device of claim 1 wherein a widest width of the magnet between tapering sides of the magnet is less than half of the widest width of the target between the second and third sides of the target.

3. The device of claim 1 wherein a longest length of the magnet between a narrow end of the magnet and an opposite side of the magnet is less than half of the length of the target between the narrow end of the target and the first side of the target.

4. The device of claim 1 wherein the first actuator scans the magnet at a constant angular speed in both scanning directions.

5. The device of claim 1 wherein the second actuator is controlled to move the magnet at a varying speed as the magnet moves with respect to the arm in a single direction.

6. The device of claim 1 wherein the second actuator is controlled to move the magnet at a constant speed as the magnet moves with respect to the arm in a single direction.

7. The device of claim 1 wherein the second actuator is controlled to stop movement of the magnet along the arm for certain times while the first actuator continues to scan the magnet.

8. The device of claim 1 wherein the magnet is a permanent magnet.

9. The device of claim 1 wherein the magnet comprises a plurality of magnets arranged in a plurality of nested patterns.

10. The device of claim 1 wherein the workpiece is a semiconductor wafer.

11. The device of claim 1 wherein the workpiece is a portion of a flat panel display.

12. The device of claim 1 wherein the target is inside the chamber and the magnet is outside of the chamber.

13. The device of claim 1 wherein the magnet is a first magnet, the device further comprising:
at least two additional substantially triangular magnets approximately equidistance apart, the at least two additional magnets opposing back surfaces of respective substantially triangular targets; and
each of the additional magnets being connected to the same first actuator, and each additional magnet being connected to a different arm and additional actuator that moves the associated magnet in a straight path along an associated arm in two opposite directions along a length of each respective target during a sputtering operation.

14. The device of claim 1 wherein the second actuator moves the magnet back and forth along the arm at a period between 1-20 seconds.

15. The device of claim 1 wherein a widest width of the magnet between tapering sides of the magnet is between one-quarter and one-half of the widest width of the target between the second and third sides of the target, and wherein a longest length of the magnet between a narrow end of the magnet and an opposite side of the magnet is between one-quarter and one-half of the length of the target between the narrow end of the target and the first side of the target.

16. A method for sputtering material onto a workpiece located in a chamber, the chamber having a substantially circular top wall, the chamber containing a plurality of substantially triangular targets supported by the top wall, the targets having narrow ends pointing toward a center of the top wall, the targets being arranged in a first plane, a front side of each target being directed into the chamber for sputtering material from the targets onto the workpiece, the method comprising:
scanning a separate substantially triangular magnet associated with each target, by a first actuator, back and forth through an arc in a second plane over each target during a sputtering operation; and
moving each magnet along an associated arm connected to the first actuator in a straight path along the arm in two opposite directions perpendicular to the arc during a sputtering operation, each magnet being moved along its associated arm by an associated second actuator,
wherein a combination of the first actuator scanning each magnet in the arc and the associated second actuator moving the magnets perpendicular to the arc causes each magnet to move only over a substantially triangular area corresponding to an area of an associated target.

17. The method of claim 16 wherein the first actuator scans each magnet at a constant angular speed in both scanning directions.

18. The method of claim 16 wherein the second actuator is controlled to move each associated magnet at a varying speed as the associated magnet moves with respect to its associated arm in a single direction.

19. The method of claim 16 wherein the second actuator is controlled to move each associated magnet at a constant speed as the associated magnet moves with respect to its associated arm in a single direction.

20. The method of claim 16 wherein the second actuator is controlled to stop movement of each associated magnet along its associated arm for certain times while the first actuator continues to scan each magnet.

21. The method of claim 16 wherein the second actuator moves its associated magnet back and forth along its associated arm at a period between 1-20 seconds.

22. The method of claim 16 wherein a widest width of each magnet between tapering sides of the magnet is between one-quarter and one-half of the widest width of its associated target between tapering sides of the associated target, and wherein a longest length of each magnet between a narrow end of the magnet and an opposite side of the magnet is between one-quarter and one-half of the length of the associated target between a narrow end of the target and an opposite side of the target.
